(19) United States
(12) Patent Application Publication
(10) Pub. No.: US 2014/0360566 A1
(43) Pub. Date: Dec. 11, 2014

(54) METHOD OF MAKING PHOTOVOLTAIC DEVICES INCORPORATING IMPROVED PNICTIDE SEMICONDUCTOR FILMS USING METALLIZATION/ANNEALING/REMOVAL TECHNIQUES

(71) Applicants: DOW GLOBAL TECHNOLOGIESD LLC, Midland, MI (US); CALIFORNIA INSTITUTE OF TECHNOLOGY, Pasadena, CA (US)

(72) Inventors: Gregory M. Kimball, Campbell, CA (US); Marty W. DeGroot, Middletown, DE (US); Harry A. Atwater, South Pasadena, CA (US); Nathan S. Lewis, La Canada, CA (US); Rebekah K. Feist, Midland, MI (US); Jeffrey P. Bosco, Pasadena, CA (US)

(21) Appl. No.: 14/373,600

(22) PCT Filed: Jan. 30, 2013
(86) PCT No.: PCT/US13/23812

§ 371 Date: Jul. 21, 2014

Related U.S. Application Data
(60) Provisional application No. 61/592,950, filed on Jan. 31, 2012.

(51) Int. Cl. H01L 21/477; H01L 31/18; H01L 31/032

(52) U.S. Cl. CPC H01L 21/477; H01L 31/032; H01L 31/1864
USPC 136/255; 438/796; 136/265

(57) ABSTRACT

The present invention provides methods of making photovoltaic devices incorporating improved pnictide semiconductor films. In particular, the principles of the present invention are used to improve the surface quality of pnictide films. Photovoltaic devices incorporating these films demonstrate improved electronic performance. As an overview, the present invention involves a methodology that metalizes the pnictide film, anneals the metalized film under conditions that tend to form an alloy between the pnictide film and the alloy, and then removes the excess metal and at least a portion of the alloy. In one mode of practice, the pnictide semiconductor is Zinc phosphide and the metal is Magnesium.

### PRIORITY

This application claims priority under 35 U.S.C. §119(e) to U.S. provisional application No. 61/592,950, titled “METHOD OF MAKING PHOTOVOLTAIC DEVICES INCORPORATING IMPROVED PNICTIDE SEMICONDUCTOR FILMS USING METALLIZATION ANNEALLING REMOVAL TECHNIQUES”, filed Jan. 31, 2012, wherein the entirety of this application is incorporated herein by reference in its entirety for all purposes.

### FIELD OF THE INVENTION

The present invention relates to methods of forming pnictide semiconductor compositions suitable for use in microelectronic devices. More specifically, the present invention relates to methods of improving the quality of pnictide semiconductor films according to a methodology that metalizes the pnictide film, anneals the metalized film under conditions that tend to form an alloy between the pnictide film and the alloy metal (s), and then removes the excess metal and at least a portion of the alloy.

### BACKGROUND OF THE INVENTION

Pnictide-based semiconductors include the Group IIB/VA semiconductors. Zinc phosphide (Zn₃P₂) is one kind of Group IIB/VA semiconductor. Zinc phosphide and similar pnictide-based semiconductor materials have significant potential as photoactive absorbers in thin film photovoltaic devices. Zinc phosphide, for example, has a reported direct band gap of 1.5 eV, high light absorbance in the visible region (e.g., greater than 10⁴ to 10⁵ cm⁻¹), and long minority carrier diffusion lengths (about 5 to about 10 μm). This would permit high current collection efficiency. Also, materials such as Zn and P are abundant and low cost.

Zinc phosphide is known to be either p-type or n-type. To date, it has been much easier to fabricate p-type zinc phosphide. Preparing n-type zinc phosphide, particularly using methodologies suitable for the industrial scale, remains challenging. This has confounded the fabrication of p-n homojunctions based upon zinc phosphide. Consequently, solar cells using zinc phosphide most commonly are constructed with Mg Schottky contacts or p/n heterojunctions. Exemplary photovoltaic devices include those incorporating Schottky contacts based upon p-Zn₃P₂/Mg and have exhibited about 5.9% efficiency for solar energy conversion. The efficiency of such diodes theoretically limits open circuit voltage to about 0.5 volts due to the about 0.8 eV barrier height obtained for junctions comprising Zn₃P₂ and metals such as Mg.

Improved efficiency and open circuit voltage would be expected, though, from p/n homojunction cells for which the junction is formed by contiguous regions of the same semiconductor material having p and n type conductivity, respectively. One exemplary advantage of a p/n homojunction would be a minimization of discontinuity in the energy band structure while the gross composition remains the same. Also, indices of refraction of the adjacent p/n material would match, minimizing reflection losses. Also, the coefficients of thermal expansion would be matched to minimize potential delamination risks.

Some investigators have suggested that a p/n homojunction can form in situ when a layer of p-type zinc phosphide is heated while in contact with magnesium. See, e.g., U.S. Pat. No. 4,342,879. Other investigators have prepared n-type zinc phosphide using molecular beam epitaxy. Other approaches to make n-type zinc phosphide also have been attempted. However, such approaches generally yield devices with poor photovoltaic behavior, if any, due at least in part to poor film quality, lack of control over film stoichiometry, and/or lack of control over formation of high quality p/n junctions.

Much research and development effort is focused upon improving the electronic performance of optoelectronic devices, particularly photovoltaic devices that incorporate pnictide-based semiconductors. One challenge involves the surface quality of the pnictide film as deposited. Often, the surface quality of such surfaces is inadequate for further device formation due to issues such as roughness, electronic defects, crystalline structure defects, contamination, and the like. Accordingly, one or more kinds of treatments are practiced in order to improve the surface quality. For example, mechanical polishing has the benefit of planarizing rough surfaces, but tends to damage surface crystal structures. Hydrogen plasma treatments clean impurities, but damage surface crystal structure. Conventional etching techniques using etching compositions such as Br₂ in methanol have been used to remove polishing and plasma damage, native oxides, and other impurities such as adventitious carbon, but then the resultant surface is of low electronic quality. Consequently, strategies for providing pnictide films with improved electronic characteristics are still needed.

### SUMMARY OF THE INVENTION

The present invention provides methods of making photovoltaic devices incorporating improved pnictide semiconductor films. In particular, the principles of the present invention are used to improve the surface quality of pnictide films. Photovoltaic devices incorporating these films demonstrate improved electronic performance. As an overview, the present invention involves a methodology that metalizes the pnictide film, anneals the metalized film under conditions that tend to form an alloy between the pnictide film and the metal(s), and then removes the excess metal and at least a portion of the alloy. Surface impurities and defects are greatly reduced. The surface is well-prepared for further device fabrication.

Observed improvements in electronic performance have been dramatic. In one set of experiments, the open circuit voltage of samples treated in accordance with the present invention was compared to the open circuit voltage of otherwise identical samples that were not treated. Surprisingly, in one experiment the open circuit voltage of the treated samples increased by a factor of six.

The resultant pnictide films can be incorporated into a wide range of microelectronic devices, including photovoltaic devices, antistatic films, antireflective stacks, electromagnetic shielding, heat-efficient electrochemical windows, electrochromic windows, electroluminescent lamps, liquid crystal and other flat panel displays, light emitting diodes, laser diodes, transparent membrane switches, touch screens, ultraviolet photoconductive detectors, thermoelectric devices, light polarization step indicators, infrared and other sensors, solid state lasers, as well as other optoelectronic and microelectronic devices.

In one aspect, the present invention relates to a method, comprising the steps of:
a. providing a pnictide semiconductor film or precursor thereof, said pnictide semiconductor film having a surface; and
b. annealing the semiconductor film or precursor thereof in the presence of at least one metal containing material under conditions effective to cause a pnictide semiconductor alloy layer to form in contact with the pnictide semiconductor film or precursor thereof; and
c. removing a portion of the semiconductor alloy layer such that a pnictide semiconductor alloy layer remains on the pnictide semiconductor film or precursor thereof.

In another aspect, the present invention relates to a photovoltaic device, comprising:
a. at least one pnictide semiconductor film:
b. a pnictide semiconductor alloy film provided on a surface of the pnictide semiconductor film, said pnictide semiconductor alloy film having a thickness of less than 50 nm; and
c. at least one additional film provided on the pnictide alloy film, wherein at least said additional film, said pnictide semiconductor film, and said pnictide alloy film form a photovoltaic junction.

### BRIEF DESCRIPTION OF THE DRAWINGS

FIG. 1 schematically illustrates how a methodology of the present invention can be used to improve a pnictide film, which is then incorporated into a photovoltaic junction such as, by way of example, solid state contact or the alternative liquid contact.

FIG. 2 schematically illustrates a photovoltaic device incorporating a pnictide semiconductor film that has been treated in accordance with the methodology of the present invention.

### DETAILED DESCRIPTION OF PRESENTLY PREFERRED EMBODIMENTS

The embodiments of the present invention described below are not intended to be exhaustive or to limit the invention to the precise forms disclosed in the following detailed description. Rather the embodiments are chosen and described so that others skilled in the art may appreciate and understand the principles and practices of the present invention. All patents, pending patent applications, published patent applications, and technical articles cited herein are incorporated herein by reference in their respective entireties for all purposes.

The principles of the present invention are used to improve the surface quality of pnictide films. Photovoltaic devices incorporating these treated films demonstrate improved electronic performance. Without wishing to be bound by theory, it is believed that the annealing step promotes a solid state interaction between the pnictide film and the overlying metal film that forms an alloy layer at the interface between the pnictide film and the metal film. From this perspective, the metal film can be viewed as a source of at least one species that is co-reactive with at least one species sourced from the pnictide film. However, the interaction between the species may be a physical and/or chemical interaction as the alloy is formed.

The present invention involves a treatment methodology that includes forming a metal film in excess on an underlying pnictide film, annealing the resultant workpiece under conditions so that an alloy forms at the interface between the pnictide and metal films, and then removing the excess metal film. All or a portion of the alloy film may be removed as well. The sequence of forming the metal film, allowing the alloy to form, and then removing the excess metal film and at least a portion of the formed alloy layer is believed to remove impurities and reduce defects at and/or proximal to the pnictide film surface. Depositing enough metal to ensure an excess of metal after the alloy is formed helps to ensure uniform passivation of the pnictide. Removal tends to provide resultant devices with improved J_{sc} (short circuit current) while also avoiding detrimental effects that might be associated were the residual metal to be left in place.

Schematically, the metal film can be viewed as an interactive scavenger of impurities and electronic defects with respect to the pnictide film. Once the “scavenger” is removed (even though a portion of its interactive products, eg., the alloy layer, might only be partially removed in some embodiments), the pnictide film is provided with a high quality, passivated surface region that is well prepared for further fabrication steps.

As one demonstration of the benefits provided by this methodology, an exemplary workpiece is provided that includes a crystalline zinc phosphide wafer supported on a silver back contact layer. A Mg layer is formed on the zinc phosphide and annealed to provide an interfacial alloy layer. The alloy layer is formed from Mg, Zn, and P and, hence, is a pnictide semiconductor alloy. Most of the Mg remains unreacted. Etching is used to remove all of the excess Mg. In addition, etching is used to remove a portion of the alloy layer, leaving a portion of the alloy layer to provide a passivation effect. The passivated sample prepared this way demonstrates greater than 600 mV V_{oc} (open circuit voltage) under AM1.5 1-sun illumination at 25° C. An otherwise identical comparison sample prepared without using the treatment of the invention showed less than 100 mV V_{oc}.

For convenience, the sequence of forming the metal film on the underling pnictide film, annealing the resultant workpiece to form an alloy layer between the pnictide and metal films, and then removing the excess metal and at least a portion of the resultant alloy film shall be referred to herein as the metallization/annealing/removal methodology.

According to the method of the present invention, a pnictide semiconductor film or precursor thereof is provided on which the treatment method will be carried out. The term “pnictide” or “pnictide compound” refers to a molecule that includes at least one pnictogen and at least one element other than a pnictogen. The term “pnictogen” refers to any element from Group VA of the periodic table of elements. These also are referred to as Group VA or Group 15 elements. Pnictogens include nitrogen, phosphorus, arsenic, antimony, and bismuth. Phosphorus and arsenic are preferred. Phosphorus is most preferred.

In addition to the pnictogen(s), the other element(s) of a pnictide may be one or more metals, and/or nonmetals. In some embodiments, nonmetals may include one or more semiconductors. Examples of suitable metals and/or semiconductors include Si, the transition metals, Group IIB metals (Zn, Cd, Hg), metals included in the lanthanoid series, Al, Ga, In, TI, Sn, Pb, combinations of these, and the like. In addition to the semiconductor materials noted above, other examples of such nonmetals include B, S, F, Se, Te, C, O, H combinations of these, and the like. Examples of nonmetal pnictides include boron phosphide, boron nitride, boron arsenide, boron antimonide, combinations of these and the like. Pnictides that include both metal and nonmetal constituents in addition to one or more pnictogens are referred to herein as mixed pnictides. Examples of mixed pnictides include (a) at least one of Zn and/or Cd, (b) at least one of P, As, and/or Sb, and (c) at least one of Se and/or S, combinations of these, and the like.

Many embodiments of metal, non-metal, and mixed pnictides are photovoltaically active and/or display semiconductor characteristics. Examples of such photovoltaically active and/or semiconducting pnictides include phosphide, nitrides, antimonides, and/or arsenides of one or more of aluminum, boron, cadmium, gallium, indium, magnesium, germanium, tin, silicon, and/or zinc. Illustrative examples of such compounds include zinc phosphide, zinc antimonide, zinc arsenide, aluminum antimonide, aluminum arsenide, aluminum phosphide, boron antimonide, boron arsenide, boron phosphide, gallium antimonide, gallium arsenide, gallium phosphide, indium antimonide, indium arsenide, indium phosphide, aluminum gallium antimonide, aluminum gallium arsenide, aluminum gallium phosphide, aluminum indium antimonide, aluminum indium arsenide, aluminum indium phosphide, indium gallium antimonide, indium gallium arsenide, indium gallium phosphide, magnesium antimonide, magnesium arsenide, magnesium phosphide, cadmium antimonide, cadmium arsenide, cadmium phosphide, combinations of these and the like. Specific examples of these include Zn₃P₂; ZnP₂; ZnAr₂; ZnSb₂; ZnP₄; ZnP; combinations of these and the like.

Preferred embodiments of pnictide compositions comprise at least one Group IIB/VA semiconductor. A Group IIB/VA semiconductor generally includes (a) at least one Group IIB element and (b) at least one Group VA element. Examples of IIB elements include Zn and/or Cd. Zn is presently preferred. Examples of Group VA elements (also referred to as pnictogens) include one or more pnictogens. Phosphorous is presently preferred.

Exemplary embodiments of Group IIB/VA semiconductors include zinc phosphide (Zn₃P₂), zinc arsenide (Zn₃As₂), zinc antimonide (Zn₃Sb₂), cadmium phosphide (Cd₃P₂), cadmium arsenide (Cd₃As₂), cadmium antimonide (Cd₃Sb₂), combinations of these, and the like. Group IIB/VA semiconductors including a combination of Group IIB species and/or a combination of Group VA species (e.g., CdₓZn_{y}P₂, wherein each x and y is independently about 0.001 to about 2.999 and x+y is 3) also may be used. In an illustrative embodiment, the Group IIB/VA semiconductor material comprises p-type and/or n-type Zn₃P₂. Optionally, other kinds of semiconductor materials also may be incorporated into the composition.

The pnictide compositions used in the practice of the present invention may be amorphous and/or crystalline as supplied or formed, but desirably are crystalline prior to carrying out the treatment according to the present invention. Crystalline embodiments may be single crystal or polycrystalline, although single crystal embodiments are preferred. Exemplary crystalline phases may be tetragonal, cubic, monoclinic, and the like. Tetragonal crystalline phases are more preferred, particularly for zinc phosphide.

Pnictide compositions having photovoltaic and/or semiconducting characteristics may be of n-type or p-type. Such materials may be intrinsically and/or extrinsically doped. In many embodiments, extrinsic dopants may be used in a manner effective to help establish a desired carrier density, such as a carrier density in the range from about 10¹³ cm⁻³ to about 10²⁰ cm⁻³. A wide range of extrinsic dopants may be used. Examples of extrinsic dopants include Al, Ag, B, Mg, Cu, Au, Cd, In, F, H, Si, Sn, Ge, Cl, Br, S, Se, Ca and others from other draft Te, N, I, combinations of these and the like.

Pnictide films in the practice of the present invention may have a wide range of thicknesses. Suitable thicknesses may depend on factors including the purpose of the film, the composition of the film, the methodology used to form the film, the crystallinity and morphology of the film, and/or the like. For photovoltaic applications, a film desirably has a thickness effective to capture incident light for photovoltaic performance. If the film were to be too thin, too much light may pass through the film without being absorbed. Layers that are too thick will provide photovoltaic functionality, but are wasteful in the sense of using more material than is needed for effective light capture and reduced fill factors due to increased series resistance. In many embodiments, pnictide films have a thickness in the range from about 10 nm to about 4 microns, or even from about 50 nm to about 1.5 microns. By way of example, a thin film having p-type characteristics that is used to form at least part of a p-n, p-i-n, Schottky junction, or the like, may have a thickness in the range from about 1 to about 5 μm, preferably about 2 to about 3 μm. A thin film having n-type characteristics that is used to form at least part of a p-n, p-i-n, or the like, may have a thickness in the range from about 0.02 to about 2 μm, preferably about 0.05 to about 0.2 μm.

Pnictide films may be formed from a single layer or multiple layers. Single layers may have a generally uniform composition throughout or may have a composition that shifts throughout the film. A layer in a multilayer stack typically has a different composition than adjacent layer(s), although the composition of nonadjacent layers may be similar or different in such embodiments.

Pnictide films desirably are supported upon a suitable substrate. Exemplary substrates may be rigid or flexible, but desirably are flexible in those embodiments in which the resultant microelectronic device may be used in combination with non-flat surfaces. A substrate may have a single or multilayer construction. When the pnictide film is to be incorporated into an optoelectronic device, the substrate may include at least a portion of those layers that would be underneath the film in the finished device if the device is built right side up. Alternatively, the substrate may be at least a portion of the layers that would be above the film in the finished device if the device is being fabricated upside down.

The treatment of the present invention may be used to dramatically improve the surface quality of the pnictide film. Often, the pnictide film as provided has a number of quality issues that desirably are addressed in order to provide optoelectronic devices with better electronic performance. Quality issues include polishing damage, native oxide, adventitious carbon, other surface impurities, and the like. Quality issues such as these can lead to problems such as undue surface defect density, undue surface trap states, undue surface recombination velocity, and the like.

One or more optional pre-treatments may be carried out on all or a portion of the pnictide film surface to better prepare the film for the metallization/anneal/removal treatment steps of the present invention. Such optional pre-treatments may be carried for a variety of reasons, including to polish the surface, to smooth the surface, to clean the surface, to rinse the surface, to etch the surface, to reduce electronic defects, oxide removal, passivation, combinations of these, and the like. For example, in one exemplary methodology, polycrystalline boules of zinc phosphide semiconductor material are grown using procedures described in the technical literature. The boules are diced into rough wafers. As an exemplary pre-pretreatment methodology, the rough wafers are polished using a suitable polishing technique. The surface quality of the wafers is further improved by an additional pre-treatment in which the wafer surfaces are subjected to that involves at least two stages of etching and at least one oxidation that in combination not only clean the pnictide film surface, but also render the film surface highly smooth with reduced electronic defects. The surface is well-prepared for further fabrication steps. This integrated etching/oxidation/etching treatment is described Assignee's co-pending U.S. Provisional patent application filed on the same date as the present application in the names of Kimball et al., titled METHOD OF MAKING PHOTOVOLTAIC DEVICES INCORPORATING IMPROVED PNICTIDE SEMICONDUCTOR FILMS, and having Attorney Docket No. Docket No 71958 (DOW0058P1), the entirety of which is incorporated herein by reference for all purposes.

After the pnictide semiconductor film is provided, and after performing any desired, optional pre-treatment(s), the pnictide semiconductor film is annealed in the presence of at least one metal-containing material under conditions effective to cause a pnictide semiconductor alloy to form in contact with the pnictide semiconductor film. A pnictide alloy is an alloy including one or more pnictogens. An alloy refers to a composition that is a mixture or solid solution composed of two or more elements. Complete solid solution alloys give single solid phase microstructure, while partial solutions give two or more phases that may or may not be homogeneous in distribution, depending on thermal (heat treatment) history. Alloys usually have different properties from those of the component elements. In the practice of the present invention, an alloy can have gradient(s) in stoichiometry due to processing techniques.

A metal species is alloyable in a resultant alloy if the alloy includes at from 0.8 to 99.2 atomic percent, preferably from 1 to 99 atomic percent of that metal based on the total metal content of the alloy. Alloyable species are distinguished from dopants, which are incorporated into semiconductor films or the like at substantially lower concentrations, e.g., concentrations in the range of 1e20 cm³ to 1e15 cm⁻³ or even less. By way of example, Mg is alloyable with Zn₃P₂ to form a Mg₃ₓZn_{3*(1-x)}P₂ alloy in which x has a value such that the Mg content may be in the metal (or cation) atomic percent range of 0.8 to 99.2 percent based on the total amount of Mg and Zn.

Exemplary metal species that would be alloyable with pnictide film compositions include one or more of Mg, Ca, Be, Li, Cu, Na, K, Sr, Rb, Cs, Ba, Al, Ga, B, In, and combinations of these. Mg is more preferred.

Annealing may be carried out in a variety of ways. According to one mode of practice, annealing occurs in the presence of a vapor comprising at least one metal-containing species that is co-reactive with the pnictide semiconductor film. The annealing occurs under conditions effective for the pnictide semiconductor film and the metal-containing species to interact to form the alloy. Without wishing to be bound, the surface of the pnictide semiconductor film is believed to be the general location of a solid state reaction between the film and the vapor. The reaction product is the alloy layer.

According to another mode of practice, annealing involves first forming a metal film on at least a portion, preferably the entirety of, the pnictide film surface. The metal-film includes at least one metal species that is alloyable with the pnictide semiconductor film. An interface is formed between the surface of the underlying pnictide film and the metal film. Without wishing to be bound, it is believed that this interface is the general location of a solid state reaction between adjacent regions of the pnictide film and metal film, described further below, in which the reaction product is an alloy layer that forms between the two reactant film layers.

The metal film may be formed on the pnictide film using any suitable technique(s). Exemplary techniques include sputtering, thermal evaporation, e-beam evaporation, other vacuum techniques, and the like. In some embodiments, RF magnetron sputtering of metal films would be suitable.

The resultant metal films may be deposited with thicknesses in a wide range. Generally, enough film should be deposited to allow formation of the desired alloy layer. In some modes of practice, enough metal film is deposited to allow excess metal to remain as a residual metal film after the alloy layer is formed. At this stage of the process, the residual metal film can be viewed as capping the alloy film and underlying pnictide film. Accordingly, it would be desirably for the metal film as deposited to have a thickness in the range of 5 to 100 nm, preferably 10 nm to 70 nm, and more preferably 30 nm to 50 nm. In an exemplary embodiment, a Mg film formed on a Zn₃P₂ film with a thickness of 50 nm would be suitable.

The pnictide and metal films are annealed under conditions effective to cause an alloy layer to form at the interface between the pnictide film and the metal film. Without wishing to be bound by theory, it is believed that the alloy results from solid state interaction among one or more species from the pnictide film and one or more species from the metal film. Consequently, it is believed that the alloy layer includes at least one alloy constituent from the pnictide film and at least one alloy constituent from the metal film.

For example, one mode of practice of the present invention involves forming an Mg film on a Zn₃P₂ film surface. Annealing these films forms an alloy layer interposed between the Zn₃P₂ and Mg films when the Mg is present in excess. The alloy is believed to have the composition Mg:Zn₃P₂. The Mg portion of this alloy is sourced from the metal film, while the Zn₃P₂ portion of the alloy is sourced from the pnictide film.

Annealing generally occurs at a temperature that is high enough to cause formation of the alloy layer in a reasonable amount of time. Yet, the temperature should be low enough to avoid undue risk of degrading the films or other components or features that might be present in the workpiece. Balancing such concerns, annealing desirably occurs at 50° C. to 300° C. for a time period from 10 seconds to 140 hours, preferably 1 minute to 72 hours, more preferably 5 minutes to 24 hours in suggested embodiments.

After annealing, a pnictide semiconductor alloy layer is formed at the interface between the underlying pnictide film and the overlying, residual metal film (if any) that remains after annealing. In some embodiments, the metal film is present in substantial excess so that only a small percentage of the metal film interacts with the pnictide film during annealing to form the alloy layer. In these embodiments, most of the original film will remain to constitute at least a portion of the residual metal film. In some instances, depending upon the conditions of annealing and the nature of the metal film, portions of the excess metal may be altered to some degree by annealing. These altered portions would then constitute at least a portion of the residual film.

Without wishing to be bound, it is believed that the alloy forms a higher bandgap material relative to the underlying pnictide semiconductor layer. Consequently, the alloy layer is analogous to a window layer and is believed to be inherently passivating due to band alignments. This hypothesis is supported by the technical literature, which reports that that Mg₃P₂ is a wider bandgap semiconductor than Zn₃P₂.

Alternative techniques can be used to form the alloy layer on the underlying pnictide semiconductor layer. One alternative approach involves heating the pnictide semiconductor layer in the presence of one or more metal-containing, vapor species incorporating one or more co-alloyable metal species of interest such Mg or others identified herein. The metal-containing, vapor species may include a metal/organic material that decomposes upon heating. By way of example, several organic species including Mg include Bis(cyclopentadienyl)magnesium, Bis(ethylcyclopentadienyl)magnesium, Bis(pentamethylcyclopentadienyl)magnesium, Bis(n-propylcyclopentadienyl)magnesium, combinations of these, and the like. Decomposition releases the metal constitutent(s). This would allow the metal(s) to be incorporated as alloy constituent(s) into the pnictide layer to form the alloy. Excess metal would tend to grow as a metal film over the alloy layer. This technique could be used to incorporate combinations of alloyable metals into the alloy layer by using multiple vapor species and/or species that include multiple metal constituents.

After the alloy layer and metal film (if any) are formed by any desired technique(s), the methodology of the present invention continues in a next step by removing this residual metal film. It is also desirable in this same removal step or in a subsequent removal step to remove all or a portion of the alloy film that formed during annealing. In many embodiments, the removal of the residual metal film and at least a portion of the alloy film occur in the same removal treatment. Any suitable removal techniques can be used including dry or wet etching techniques. Wet etching techniques include spray techniques and immersion techniques. After the material(s) are removed, the workpiece surface can be rinsed and dried or otherwise processed for further handling.

An exemplary removal technique involves etching the workpiece under ambient temperature with an aqueous etching composition having a ph greater than 8, preferably greater than 8.5. An exemplary etching composition in this class is formulated from EDTA (often sourced as Na₂EDTA) and aqueous hydrogen peroxide. The hydrogen peroxide solution can have a peroxide concentration selected from a wide range, e.g., in the range from 0.01 to 30 weight percent H₂O₂ based on the total weight of the peroxide solution. A concentration of 10 weight percent is suitable in one embodiment. The etching composition is formed by formulating the EDTA in the peroxide solution at any suitable concentration, e.g., at an EDTA concentration in the range from 0.1 mM to 100 mM in illustrative embodiments. A concentration in the range of 20 mM to 50 mM EDTA would be more preferred. In one illustrative embodiment, an etching composition is formed from 20 mM EDTA in 10% aqueous hydrogen peroxide. This etching composition has a pH of about 10. In another illustrative embodiment, an etching composition is formed from 50 mM EDTA in 10% aqueous hydrogen peroxide. This etching composition has a pH of about 10. In one illustrative embodiment, an etching composition is formed from 5 mM EDTA in 10% aqueous hydrogen peroxide. This etching composition has a pH of about 9.

There are a wide variety of other exemplary etching reagents that can be used to remove the excess metal film and at least a portion of the alloy layer. Examples include a non-aqueous etching composition such as pyridinium triflate in THF or CAN (such as at a concentration of 5 mg/ml). Combinations of etching reagents also may be used sequentially or in combination.

Any of the treatment steps described herein may occur in a protected environment to protect the pnictide film and its substrate from the ambient. In some embodiments, the protected environment may include an atmosphere of nitrogen, argon, carbon dioxide, clean dry air, hydrogen, helium, combinations of these, and the like. The pressure may be at ambient pressure, a vacuum, or at a pressure above ambient pressure. For example, exemplary pressures may be in the range from 1×10⁻¹² torr to 760 torr.

In many embodiments, only a portion of the alloy layer is removed, so that a remainder of the alloy layer remains over the pnictide semiconductor layer.

As one benefit, the residual alloy protects and/or passivates the underlying pnictide semiconductor material. If all the entirety of the alloy is removed, the effect of the surface passivation process could be negated A combination comprising the pnictide semiconductor film and the alloy layer would then be incorporated into the desired optoelectronic or other microelectronic device, e.g., a photovoltaic device, according to one or more additional fabrication steps. If a remainder of the alloy layer is present after the removal step, generally it is desirable that the alloy layer be as thin as practical to facilitate better electronic performance and yet be thick enough to provide desired passivation effect(s). As general guidelines, the remaining alloy layer desirably has a thickness of less than 50 nm, preferably less than 20 nm, more preferably less than 10 nm. To provide a desired passivation effect, the remaining alloy layer desirably has a thickness of at least 0.1 nm, more desirably at least 1 nm. In preferred embodiments, the remaining alloy layer has a thickness in the range from 1 nm to 5 nm.

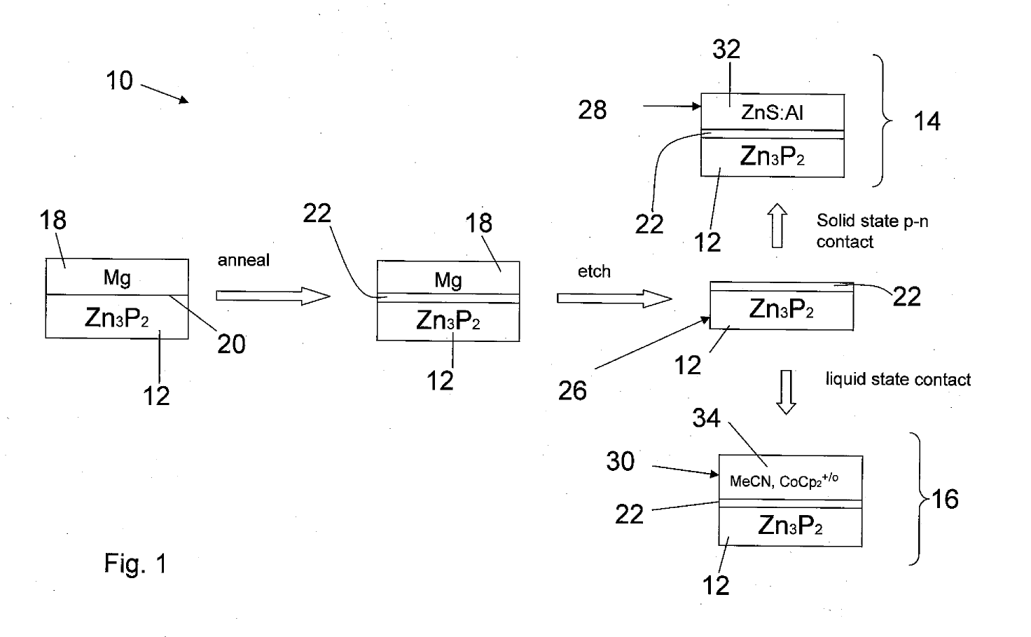

Following treatment according to the methodology of the present invention, the pnictide film can be incorporated into a wide range of microelectronic and optoelectronic devices. FIG. 1 schematically illustrates how the methodology 10 of the present invention can be used to improve a pnictide film 12, which is then incorporated into a photovoltaic junction such as, by way of example, solid state photovoltaic junction 14 or the alternative liquid junction 16. For purposes of illustration, the pnictide film 12 is zinc phosphide. As an initial step of methodology 10, a metal film 18 is formed on pnictide film 12. An interface 20 is provided between films 12 and 18.

The films 12 and 18 are annealed. Alloy layer 22 forms between films 12 and 18. In the illustrated embodiment, the alloy layer includes an alloy of Mg, Zn, and P. Preferred embodiments of this alloy composition include 0.1 to 60, more preferably 5 to 25% atomic percent Mg based on the total amount of Mg and Zn. There is sufficient excess metal film 18 such that a portion of metal film 18 remains after the alloy layer 22 is formed by annealing.

The excess metal film 18 and at least a portion of the alloy film 22 are removed. Optionally, the entirety of the alloy film 22 can be removed to expose the pnictide film 12. Any suitable technique, such as an etching technique commonly practiced by those in the semiconductor industry, can be used for this removal. Exemplary techniques include chemical vapor etch techniques, ion etch techniques, plasma etch techniques, laser ablation techniques, chemical etch techniques, mechanical polishing, wet bench techniques, spray etching techniques, dry etching techniques, combinations of these, and the like.

The resultant workpiece 26 can then be incorporated into a photovoltaic junction in a variety of ways. For purposes of illustration, FIG. 1 shows two alternative options for forming a solid state junction as shown by workpiece 28 or a liquid contact as shown by workpiece 30. To make the solid state contact, it can be appreciated that zinc phosphide tends to have p type characteristics in most instances. Accordingly, a p-n heterojunction can be formed by depositing a suitable n-type film 32 on the alloy layer 22. For purposes of illustration, the n-type film 32 formed on alloy layer. 22 is zinc sulfide doped with aluminum. Such a layer can formed techniques described in Assignee's co-pending U.S. Provisional patent application filed on the same date as the present application in the names of Boscoe et al., titled METHOD OF MAKING PHOTOVOLTAIC DEVICES WITH REDUCED CONDUCTION BAND OFFSET BETWEEN PNICTIDE ABSORBER FILMS AND EMITTER FILMS., and having Attorney Docket No. Docket No 71957 (DOW0057P1), the entirety of which is incorporated herein by reference for all purposes.

To form a liquid contact, a layer 34 including a material such as MeCN, CoCp₂^{+/o} is provided on the alloy layer 22.

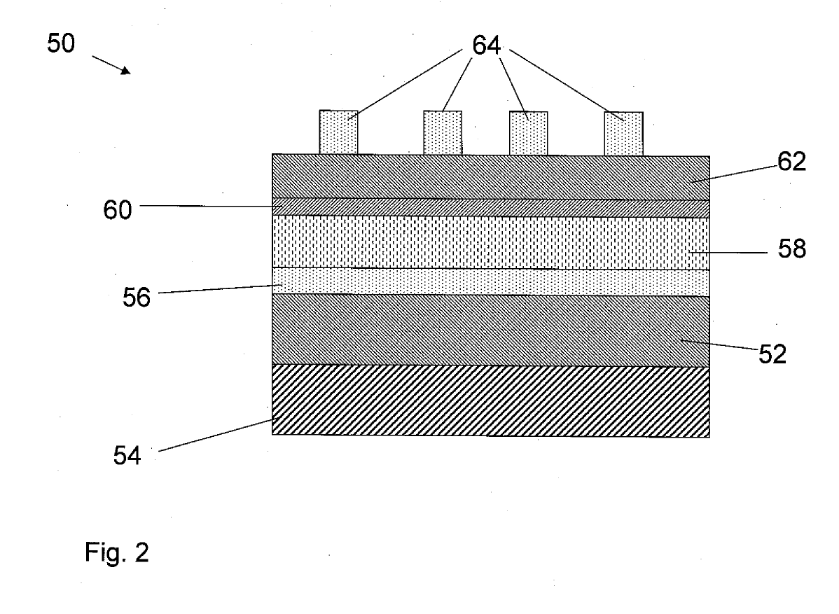

FIG. 2 schematically illustrates a photovoltaic device 50 incorporating a pnictide semiconductor film 52 that has been treated in accordance with the methodology of the present invention. For purposes of illustration, film 52 has p-type characteristics and functions as an absorber region. Film 52 is supported upon substrate 54. Pnictide alloy layer 56 is provided on film 52. Without wishing to be bound, it is possible that the alloy layer 56 may function as an “I” layer in the resultant photovoltaic junction. If so, the resulting junction would be a p-i-n junction. An n-type emitter layer 58 is provided over the alloy layer 56. Window layer 60 is provided over the emitter layer 58. Transparent electrode layer 62 is formed over window layer 60. Collection grid 64 is formed over layer 62. One or more environmental protection barriers (not shown) can be used to protect device 50 from the ambient.

The present invention will now be further described with reference to the following illustrative examples.

### Example 1

A substrate is provided that includes a crystalline Zn₃P₂ wafer on a Ag back contact layer. A Mg (co-reactive species) layer is deposited onto the zinc phosphide wafer. The structure is annealed to produce an interfacial alloy region between the zinc phosphide and the Mg, with substantially all of the co-reactive species remaining unreacted. This excess co-reactive species layer is removed via a chemical etch process. A portion of the alloy also is removed so that the remaining alloy thickness is under 20 nm. The passivated Zn₃P₂ samples prepared in this fashion have been shown to exhibit >600 mV Voc, while comparative examples (prepared without the co-reactive species) showed Voc<100 mV.

### Example 2

The Zn₃P₂ samples used in this example are grown by a physical vapor transport process. Red phosphorus chips and zinc shot (99.9999%, Alfa Aesar) are combined at 850° C. to form Zn₃P₂ powders. The powders are then grown into polycrystalline boules 1 cm in diameter and 4 cm in length, with grain sizes of about 1-5 mm². The resulting crystals were diced with a diamond saw and had as-grown resistivity between 1000-2000 Ωcm. Annealing with white phosphorus in sealed ampoules at 400° C. for 20 hours was effective at reducing the wafer resistivity to ˜20 Ωcm due to doping by phosphorus interstitials. Both undoped and P-doped samples were polished with diamond paste to produce Zn₃P₂ wafers. Samples with 1 cm diameter and 500-600 μm thickness were etched for 30 s in 2-3% (v:v) Br₂ in CH₃OH, rinsed in CH₃OH, dried under a stream of N₂, and used promptly thereafter.

We fabricated Zn₃P₂ semiconductor/liquid junction devices from as grown Zn₃P₂ wafers. Mg films of thickness ˜200 nm were deposited by rf magnetron sputtering on freshly etched Zn₃P₂ wafers without any sputter etching of the sample. Back contacts of Ag print were deposited. The samples were subjected to 100° C. for 100 min in air and then cooled to room temperature. The samples were etched using an aqueous H₂O₂ (10%)/Na₂EDTA (10 mM), pH 10 solution under ambient conditions for <1 min. to remove all unreacted Mg. A portion of the resultant alloy is removed so that the remaining alloy thickness is under 20 nm. The samples were rinsed with deionized H₂O and dried with N₂. The samples were immediately transferred to an inert atmosphere glove box, wherein the samples are immersed in an acetonitrile solution containing 0.5 M NBu₄[PF₆], 20 mM, CoCp₂^{+/0}. The Voc measured under 1 sun illumination was >600 mV.

Other embodiments of this invention will be apparent to those skilled in the art upon consideration of this specification or from practice of the invention disclosed herein. Various omissions, modifications, and changes to the principles and embodiments described herein may be made by one skilled in the art without departing from the true scope and spirit of the invention which is indicated by the following claims.

1. A method, comprising the steps of:
a. providing a pnictide semiconductor film or precursor thereof, said pnictide semiconductor film or precursor thereof having a surface;
b. annealing the semiconductor film or precursor thereof in the presence of at least one metal containing material under conditions effective to cause a pnictide semiconductor alloy layer to form in contact with the pnictide semiconductor film or precursor thereof; and
c. removing a portion of the semiconductor alloy layer such that a pnictide semiconductor alloy layer having a thickness of less than 20 nm remains on the pnictide semiconductor film or precursor thereof.

2. The method of claim 1, wherein step (b) comprises:
i. forming a metal-containing film on at least a portion of the pnictide semiconductor film or precursor thereof; said metal-containing film comprising at least one metal-containing species, wherein the at least one metal-containing species is alloyable with at least a portion of the pnictide semiconductor film or precursor thereof, and wherein an interface is provided between the pnictide semiconductor film or precursor thereof and the metal-containing film; and
ii. annealing the pnictide semiconductor film or precursor thereof and the metal-containing film in a manner effective to cause the pnictide semiconductor alloy layer to form in contact with the pnictide semiconductor film or precursor thereof.

3. The method of claim 2, wherein the metal-containing film is in excess such that the pnictide semiconductor alloy layer forms between the pnictide semiconductor film or precursor thereof and a residual metal film that remains after annealing; and wherein the method further comprises removing the residual metal film and at least a portion of the pnictide semiconductor alloy layer.

4. The method of claim 1, further comprising the step of removing a portion of the semiconductor alloy layer such that a pnictide semiconductor alloy layer having a thickness of less than 10 nm remains on the pnictide semiconductor film or precursor thereof.

5. The method of claim 1 wherein the annealing step occurs in the presence of a vapor comprising the at least one metal-containing species.

6. The method of claim 1, further comprising the step of incorporating the pnictide semiconductor film and pnictide semiconductor alloy layer into a photovoltaic device.

7. The method of claim 1, wherein the pnictide semiconductor film comprises a Group IIB/VA semiconductor.

8. The method of claim 2, wherein the metal-containing film as deposited has a thickness in the range from about 5 nm to about 100 nm and the pnictide semiconductor film or precursor thereof as deposited has a thickness in the range from about 1μ to about 2 mm.

9. The method of claim 1, wherein the pnictide semiconductor film or precursor thereof comprises at least one of Zn and P.

10. The method of claim 1, wherein the metal-containing species comprises Mg.

11. The method of claim 2, wherein the at least one metal-containing species comprises at least one metal selected from Mg, Ca, Be, Li, Cu, Na, K, Sr, Rb, Cs, Ba, Al, Ga, B, In, and combinations thereof.

12. A photovoltaic device, comprising:
a. at least one pnictide semiconductor film;
b. a pnictide alloy film provided on a surface of the pnictide semiconductor film, said pnictide alloy film having a thickness of less than 50 nm; and
c. at least one additional film provided on the pnictide alloy film, wherein at least said additional film, said pnictide semiconductor film, and said pnictide alloy film form a photovoltaic junction.

13. The device of claim 12, wherein the pnictide semiconductor film comprises at least one of Zn and P.

14. The device of claim 12, wherein the pnictide alloy film comprises Mg.

15. The device of claim 12, wherein the pnictide alloy film comprises Mg, Zn and P.

16. The device of claim 12, wherein the pnictide alloy film comprises at least one metal selected from Mg, Ca, Be, Li, Cu, Na, K, Sr, Rb, Cs, Ba, Al, Ga, B, In and combinations thereof.

17. The device of claim 12, wherein the photovoltaic junction is a Schottky barrier.

18. The device of claim 12, wherein the additional film comprises Mg.

19. The device of claim 12, wherein the photovoltaic junction is a p-n junction.

20. The device of claim 12, wherein the photovoltaic junction is a p-i-n junction.
